(19) United States
(12) Patent Application Publication
(10) Pub. No.: US 2007/0128820 A1
(43) Pub. Date: Jun. 7, 2007

(54) Apparatus and method of fabricating a MOSFET transistor having a self-aligned implant

(75) Inventors: Amlan Majumdar, Portland, OR (US); Suman Datta, Beaverton, OR (US); Justin K. Brask, Portland, OR (US); Robert S. Chau, Beaverton, OR (US); Jack T. Kavalieros, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Intel Corporation

(21) Appl. No.: 11/294,730

(22) Filed: Dec. 5, 2005

(51) Int. Cl. H01L 21/331

(52) U.S. Cl. 438/369

(57) ABSTRACT

A method including introducing an implant of a dopant species into an active region of a device substrate, the dopant species comprising a conductivity type such that a conductivity of the implant is the same as a conductivity of a well of the active region wherein the introduction is aligned to junction regions of a device structure. An apparatus and system comprising an active device region of a substrate, the active device region comprising a well of a first conductivity, junction regions of a different second conductivity formed in the active region and separated by a channel and an implant of a dopant species in the well, the dopant species comprising a conductivity type such that a conductivity of the implant is the same as the first conductivity of the well and the implant is aligned to the junction regions.

### BACKGROUND

1. Field

Circuit devices and methods for forming circuit devices.

2. Background

A metal oxide semiconductor field effect transistor (MOSFET) is a common element of an integrated circuit such as a microprocessor or other circuit. The transistor typically includes a source and drain junction region formed in a semiconductor substrate and a gate electrode formed on a surface of the substrate. A gate length is generally the distance between the source and drain junction region. Within the substrate, the region of the substrate beneath the gate electrode and between the source and drain junctions is generally referred to as a channel with a channel length being the distance between the source and drain junctions.

A transistor device works generally in the following way. Carriers (e.g., electrons, holes) flow between source junction and drain junction by the establishment of contacts to the source and drain regions. In order to establish the carrier flow, a voltage is applied to the gate electrode to form an inversion layer of carriers in the channel. The minimum amount of gate voltage is generally referred to as a threshold voltage (Vₜ).

As noted above, many transistor devices are formed in a semiconductor substrate. The substrate body may be a bulk silicon substrate or a silicon on insulator (SOI) substrate. To form ohmic contacts to carriers in the channel, dopants are introduced (e.g., via ion implantation) into the substrate. Representatively, an N-type transistor device may have source and drain regions (and gate electrode) doped with an N-type dopant such as arsenic. The N-type regions are formed in a well that has previously been formed in the semiconductor substrate as a P-type conductivity. A suitable P-type dopant is boron.

The silicon and SOI body described above are designed to be fully depleted (i.e., removing of essentially all bulk charge carriers by an electric field). Fully depleted FET transistors tend to have better gate control on a channel potential than planar MOSFET devices at low drain bias V_{DS}. Full depletion however, does not ensure better short-channel effects (SCEs) at high V_{DS} as the drain electric field can reach the source end through the substrate in bulk silicon wafers or through a buried oxide (BOX) layer in SOI wafers. In general, it is desired that SCEs are low such that the transistor off-state leakage current, I_{OFF}, (i.e., a current flowing between source and drain regions when a transistor is in an off state) remains as low as possible. SCEs may be determined by monitoring the sub threshold slope (SS) and drain induced barrier lowering (DIBL). Subthreshold slope (SS), which is a measure of the gate coupling to the channel potential, is defined as SS=dV_{G}/d[log I_{DS}], where V_{G} is the gate voltage and I_{DS} is the drain-to-source current. Drain induced barrier lowering (DIBL), which is a measure of the threshold voltage shift versus drain bias, is defined as DIBL=(V_{TLIN}−V_{TSAT})/(V_{DSAT}−V_{DLIN}). V_{TLIN} is the linear threshold voltage at low drain bias V_{DLIN}, typically 50 mV. V_{STAT} is the saturate threshold voltage at high drain bias V_{DSAT}, which is typically in the range of from 1 to 1.2V for current generation of logic transistors. A steeper SS and/or reduced DIBL shift indicates lower I_{OFF}.

Reduced drain-to-source coupling leads to better SCEs. Drain field penetration (i.e., drain-to-source coupling), may be reduced by scaling the substrate body size (e.g., thin body width W_{SI} for double-gated transistors such as FinFETs, and thin T_{SI} and W_{SI} for triple-gated transistors such as tri-gates) or by introducing heavy doping in the substrate of bulk Si wafers or the Si body in SOI wafers. Very small body dimensions, however, are not desirable because of a potential for large external resistance (R_{EXT}).

In addition, heavy doping in the body is generally achieved by locally implanted dopants (P-type in N-type metal oxide semiconductor FETs (NMOSFETs) and N-type dopants in P-type metal oxide semiconductor FETs (PMOSFETs) introduced in the substrate body and in the case of the SOI substrate, in the Si body. Such implants are referred to as “halo” implants. Typical halo implants for NMOSFETs include boron and indium (In)). Halo implants for PMOSFETs include arsenic (As), antimony (Sb), and phosphorous (P). These halos are typically implanted at an angle resulting in potential overlap between the halos and source/drain (S/D) regions and/or tip regions.

Although devices including halos show an improvement in short channel effects over devices without halos, the overlapping of the halos are a source of parasitic capacitance. This parasitic capacitance dilutes the speed CV/I gain obtained from the gate length scaling. This occurs because at the region of overlap a P-N junction forms between the source/drain (S/D) regions (e.g., N-Type semiconductor) and the halo (e.g., P-Type semiconductor). When this junction forms, the two sides (S/D region and halo side) try to equalize the Fermi level. In the process, the P side loses holes and the N side loses electrons resulting in a layer having fixed negative acceptors on the P side and fixed positive donors on the N side. This region of charge depletion is referred to as the depletion layer (DL). The width of the DL is inversely proportional to the square root of the doping densities on each side. In general, the narrower the DL, the higher the parasitic junction capacitance. Accordingly, in the case of heavy doping, the P-N junction region becomes a P+-N+ junction resulting in a narrower DL and in turn increased parasitic capacitance.

### BRIEF DESCRIPTION OF THE DRAWINGS

The features, aspects, and advantages of the invention will become more thoroughly apparent from the following detailed description, appended claims, and accompanying drawings in which:

FIG. 1 shows a cross-sectional view of a portion of a circuit substrate including a transistor device having a first spacer and a removable gate stack.

FIG. 2 shows the device of FIG. 1 after the further processing operation of etching the removable gate stack.

FIG. 3 shows the device of FIG. 1 after the further processing operation of forming a self-aligned implant.

FIG. 4 shows the device of FIG. 1 after the further processing operation of reforming the gate stack.

FIG. 5 shows the device of FIG. 1 after the further processing operations of etching the oxide layer and forming a second spacer and salicide.

FIG. 6 shows a cross-sectional view of a portion of a circuit substrate including a SOI substrate and transistor device having a first spacer and removable gate stack.

FIG. 7 shows the device of FIG. 6 after the further processing operation of etching the gate stack.

FIG. 8 shows the device of FIG. 6 after the further processing operation of forming a self-aligned implant.

FIG. 9 shows the device of FIG. 6 after the further processing operation of reforming the gate stack.

FIG. 10 shows the device of FIG. 6 after the further processing operation of etching the oxide layer and forming a second spacer and salicide.

FIG. 11 shows a graphical representation of short channel effects as indicated by subthreshold slope and drain induced barrier lowering.

FIG. 12 shows a computer system including a microprocessor having transistors formed according to an embodiment shown in FIGS. 1-11.

### DETAILED DESCRIPTION

As noted above, heavy doping introduced within the substrate to reduce SCEs, such as by traditional halo implantation, results in high parasitic capacitance due to the overlap between the halos and S/D regions. Accordingly, improved transistor switching speeds at shorter channel lengths may not be fully realized.

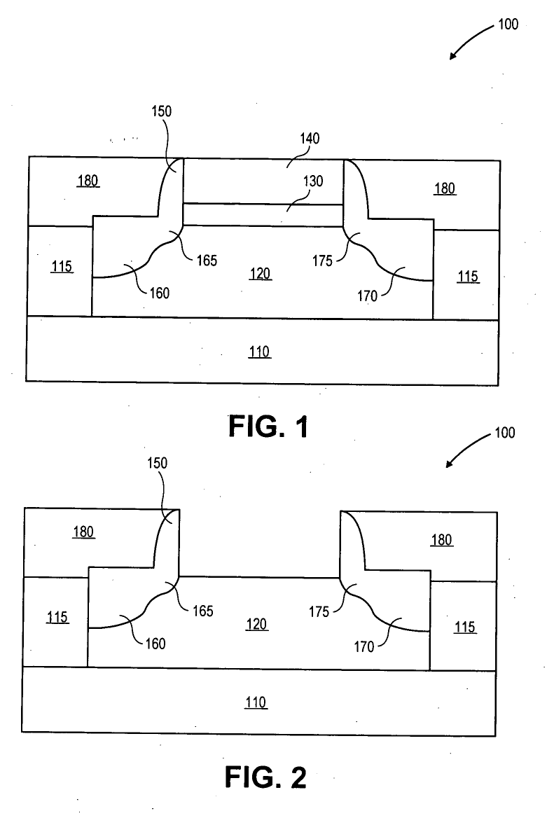

FIG. 1 shows a cross-sectional view of a portion of a circuit substrate having a transistor device formed thereon. Structure 100 may form part of a wafer in which multiple chips or die will be formed. Structure 100 includes substrate 110 of a single crystal semiconductor material, representatively silicon. An active region or area of substrate 110 is defined by isolation structures, such as shallow trench isolation (STI). FIG. 1 shows STI 115.

Formed in and on an active area substrate 110 in FIG. 1 is a transistor device. Representatively, the transistor device is an NMOSFET, formed in a P-type well 120. The transistor device includes a gate dielectric 130 formed on the surface of substrate 110 (e.g., on a top surface as viewed). Gate dielectric 130 may be grown or deposited. An example of a gate dielectric 130 that is typically grown by thermal techniques over substrate 110 is silicon dioxide (SiO2). In an alternative embodiment, gate dielectric 130 may be deposited (e.g., by chemical vapor deposition (CVD)). After gate dielectric 130 is formed, gate electrode 140 is deposited over gate dielectric 130 to form a removable gate stack. Examples of a suitable gate electrode 140, may be, for example, polysilicon. First sidewall spacer 150 is formed adjacent the gate stack (on the sides of).

The device shown in FIG. 1 also includes a raised source region 160 and drain region 170. In an NMOSFET, source region 160 and drain region 170 are both N-type. Source region 160 includes tip implant 165 (e.g. lightly doped source) formed, for example, as self-aligned to the gate stack (by an implant prior to formation of first spacers 150). The bulk of source region 160 is aligned to first spacers 150 on the gate stack (by an implant after first spacers 150 are formed). Similarly, drain region 170 includes tip implant 175 (e.g. a lightly doped drain) substantially aligned to the gate stack. The bulk of drain region 170 is aligned to spacers 150 on the gate stack. After formation of source region 160 and drain region 170, interdielectric layer (ILD) 180 is deposited and polished resulting in a planarized layer. ILD layer 180, may be, for example, an oxide layer of silicon dioxide (SiO₂) or silicon nitride (Si₃N₄) material. Polishing may be achieved, for example by, a chemical mechanical polishing (CMP) technique or any similar technique providing a planarized substrate surface.

FIG. 2 shows the structure of FIG. 1 after the further processing operation of removing gate electrode 140 and gate dielectric 130 such as by etching. Suitable etchants may include, but are not limited to, liquid or gaseous chemicals such as, for example hot phosphoric acid.

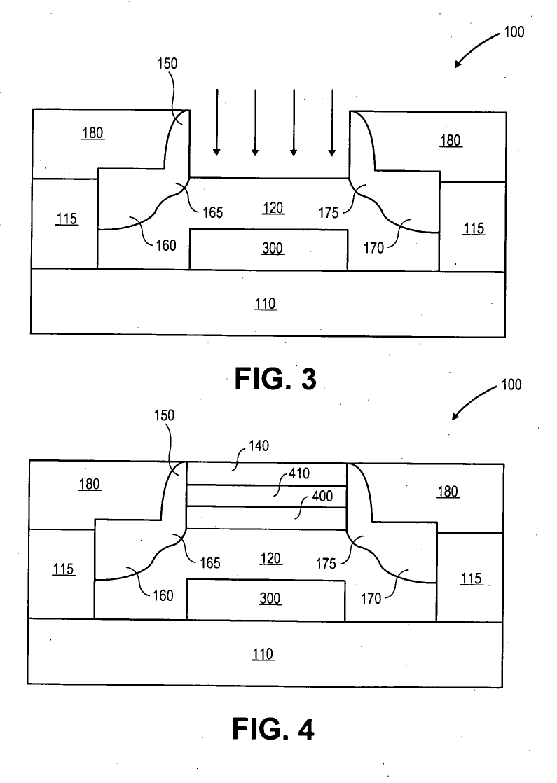

FIG. 3 shows the device of FIG. 1 after the further processing operation of forming a self-aligned implant of a dopant species (“ground plane”). After etching of gate electrode 140 and gate dielectric 130, an implant of a dopant species is introduced into an active region of well 120 of substrate 110. This forms ground plane 300 that is self-aligned to the source region 160 and the drain region 170. The dopant species may have a conductivity type such that a conductivity of the implant is the same as a conductivity of well 120 of the active region. For example, where well 120 is a P-type conductivity, the dopant species may be boron. At this stage, all dopants introduced into the transistor, namely, well 120, source region 160, source tip 165, drain region 170, drain tip 175, and ground plane 300, are activated by a thermal anneal step. Thermal annealing is typically done in the 900-1100° C. temperature range.

The dopant is introduced by implanting the dopant through the opening created by the removed gate electrode 140 and dielectric 130 to a depth sufficient to achieve the desired effects. Suitable depth of the implants to form the ground plane 300 is in the range of 200 angstroms (Å) to 500 Å. To decrease parasitic capacitance resulting from overlap of a dopant implant and source 160 and drain 170 regions, dopant implant 300 is self-aligned to source 160 and drain 170 junction regions. In an alternative embodiment, a second self-aligned dopant implant may be introduced at another depth. In this aspect, the self-aligned implants 300 are formed by introducing dopant ions such as, for example, boron into substrate 110 in a vertical direction instead of at an angle, as is used in traditional halo implantation. In an alternative embodiment, the dopant may be implanted at any angle and dose suitable for achieving the desired results. The ILD 180 and first spacers 150 act to block the dopants from penetrating into tips 165 and 175 and raised source 160 and drain 170. Thus, in one embodiment, ILD 180 and first spacer 150 are of a sufficient height (e.g. at least approximately 1000 Å) to ensure proper alignment. If the dopants are not self-aligned (i.e. overlapping), a possibility of a large parasitic capacitance may result due to a formed P+/N+ junction. Separating self-aligned implant 300 by self alignment decreases the P dopant concentration near the N+ source 160 and drain 170 regions thereby causing the junction to return to a more desirable P/N+ junction concentrations. Penetration of the dopants into tips 165, 175 and/or source 160 and drain 170 regions is also undesirable as it can lead to tip compensation and high external resistance R_{EXT}.

FIG. 4 illustrates a further processing operation including reformation of a high-K/metal gate stack. In this embodiment, high-k oxide layer 400 is deposited on substrate 110 followed by a metal layer 410. High-k oxide layer 400 may be deposited to a thickness of, for example, approximately 10 Å to 100 Å. Metal layer 410 may be deposited to a thickness of, for example, approximately 10 Å to 1000 Å. Metal layer 410 may be, for example, tantalum nitride (TaN). The high-k/metal gate stack enables oxide scaling without an increase in gate leakage current I_{G}. High I_{G} can increase the off-state transistor current (I_{OFF}). Gate electrode 140 is then deposited on metal layer 410. As previously described, gate electrode 140 may be, for example, a polysilicon material. Gate electrode 140 may be deposited to a thickness of, for example, approximately 600 Å to 1200 Å.

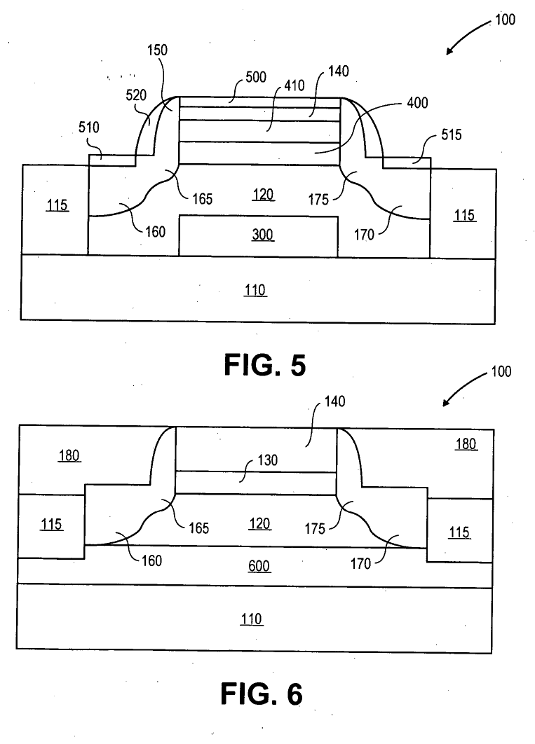

FIG. 5 illustrates structure 100 after the further processing operation of etching ILD 180 and forming second spacers 520 and salicide layers 500, 510 and 515. Second spacers 520 are formed adjacent to first spacers 150 by, for example, depositing a layer of silicon dioxide and subsequently etching the layer to form second spacers 520 along a side of first spacer 150 opposite the gate. The salicide layers 500, 510, 515 may be formed by depositing a refractory metal over polysilicon gate 140 and source 160 and drain 170 regions. The salicide is formed by reaction with underlying polysilicon layer 140 and silicon source 160 and drain regions 170 by an alloy operation. Lastly, unrefracted metal left behind on top of second spacers 520 is removed by selective wet chemical etch.

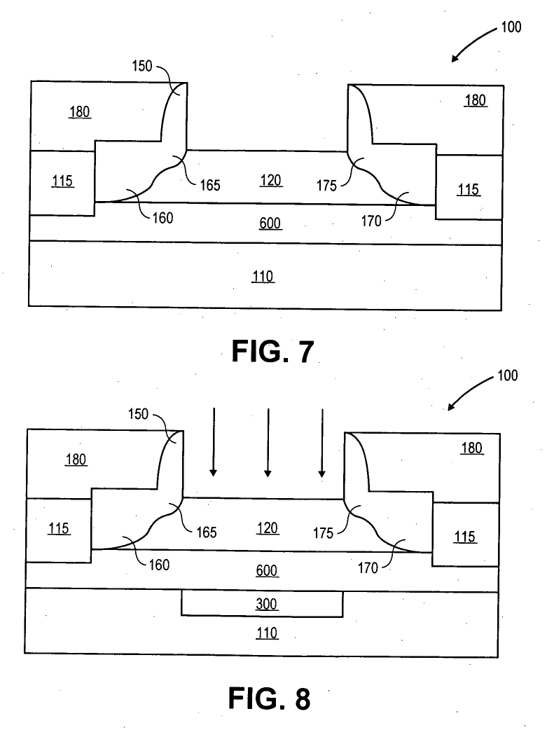

FIG. 6 shows a cross-sectional view of a portion of a circuit substrate including a SOI substrate and transistor device having a first spacer 150 and removable gate stack. Similar to the device show in FIGS. 1-5, formed in and on substrate 110 in FIG. 1 is a transistor device. Representatively, the transistor device is an NMOSFET, formed in a P-type well 120. The transistor device includes a gate dielectric 130 formed on the surface of substrate 110. Gate dielectric 130 may be grown or deposited. In this embodiment, however, substrate 110 is a SOI having a buried oxide layer (BOX) 600. FIG. 7 shows the structure of FIG. 6 after the further processing operation of etching gate electrode 140 and gate dielectric 130 to form an opening as described above.

FIG. 8 shows the device of FIG. 6 after the further processing step of forming a self-aligned implant 300 below BOX layer 600 according to the process previously described. In an alternative embodiment, self-aligned implant 300 may be formed above BOX layer 600. Still further at least two ground planes 300 may be formed, one on top of BOX layer 600 and one below BOX layer 600. It is further noted that ground planes 300 may be formed above, below or within BOX layer 600. The dopant species may have a conductivity property similar to a conductivity of well 120 of the active region. For example, where well 120 is P-type conductivity, the dopant species may be boron.

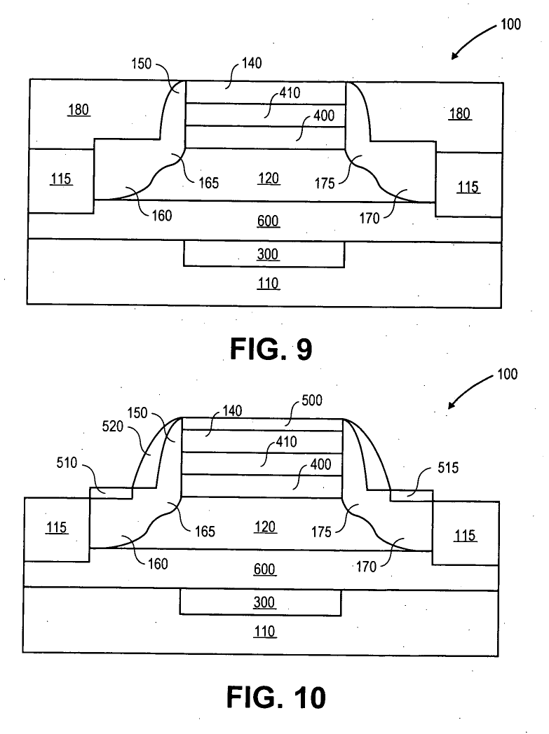

FIG. 9 illustrates a further processing operation including reformation of a gate stack. In this embodiment, a high-k oxide layer 400 is deposited on substrate 110 followed by a metal layer 410 and gate electrode 140 according to the previously described technique.

FIG. 10 illustrates structure 100 after the further processing operation of etching ILD 180 and forming a second spacer 520 and salicide layers 500, 510 and 515 according to the previously described techniques.

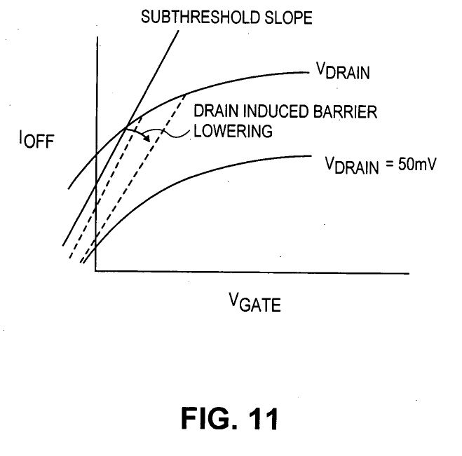

FIG. 11 shows a graphical representation of short channel effects as indicated by subthreshold slope and drain induced barrier lowering. As illustrated in FIG. 11, I_{OFF} decreases as the slope of the subthreshold slope becomes steeper and/or drain induced barrier lowering shift decreases.

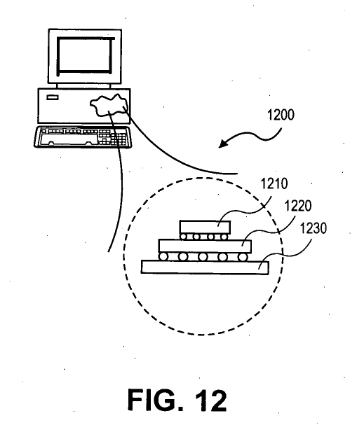

FIG. 12 shows a cross-sectional view of an integrated circuit package that can be physically and electrically connected to a printed wiring board or printed circuit board (PCB) to form an electronic assembly. The electronic assembly can be part of an electronic system such as a computer (e.g., desktop, laptop, handheld, server, etc.), wireless communication device (e.g., cellular phone, cordless phone, pager, etc.), computer-related peripheral (e.g., printer, scanner, monitor, etc.), entertainment device (e.g., television, radio, stereo, tape and compact disc player, video cassette recorder, MP3 (motion picture experts group, audio layer 3 player, etc.), and the like. FIG. 12 illustrates the package is part of a desktop computer. FIG. 12 shows electronic assembly 1200 including die 1210 physically and electrically connected to package substrate 1210. Die 1210 is integrated circuit die, such as a microprocessor die having transistor structures formed as described with reference to FIGS. 1-11. Electrical contact points (e.g., contact pad on a surface die 100) are connected to package substrate 1220 through, for example, a conductive bump layer. Package substrate 1220 may be used to connect die 1210 to printed circuit board 1230 such as a motherboard or other circuit board.

In the preceding detailed description, specific embodiments are illustrated, including a device having implants for modifying device performance. It will, however, be evident that various modifications and changes may be made thereto without departing from the broader spirit and scope of the invention as set forth in the claims. For example, N-type devices have been described. It is contemplated that, the apparatus and method is suitable for P-type devices. The specification and drawings are, accordingly, to be regarded in an illustrative rather than a restrictive sense.

What is claimed is:

1. A method comprising:
introducing an implant of a dopant species into an active region of a device substrate, the dopant species comprising a conductivity type such that a conductivity of the implant is the same as a conductivity of a well of the active region wherein the introduction is aligned to junction regions of a device structure.

2. The method of claim 1, wherein prior to introducing the implant, the method further comprising:
forming the junction regions.

3. The method of claim 1, further comprising:
introducing a second implant of the dopant species into the active region, wherein the introduction is aligned to the junction regions.

4. The method of claim 1, wherein the implant is introduced through an opening formed after removal of a gate stack.

5. The method of claim 1, further comprising depositing a gate stack after introducing the implant to enable oxide scaling without increasing gate leakage.

6. The method of claim 5, wherein the gate stack comprises a high-k oxide layer, a metal layer and a polysilicon layer.

7. An apparatus comprising:
an active device region of a substrate, the active device region comprising a well of a first conductivity;
junction regions of a different second conductivity formed in the active region and separated by a channel; and
an implant of a dopant species in the well, the dopant species comprising a conductivity type such that a conductivity of the implant is the same as the first conductivity of the well and the implant is aligned to the junction regions.

8. The apparatus of claim 7, further comprising a second implant of the dopant species aligned to the junction regions.

9. The apparatus of claim 7, further comprising a gate stack comprising a high-k oxide layer, a metal layer and a polysilicon layer.

10. The apparatus of claim 7, wherein the species is selected from the group consisting of arsenic, phosphorous and antimony.

11. The apparatus of claim 7, wherein the species is boron.

12. A system comprising:
a computing device comprising a microprocessor, the microprocessor coupled to a printed circuit board, the microprocessor comprising a substrate having a plurality of circuit devices including transistors, wherein a transistor comprises:
an active device region of a substrate, the active device region comprising a well of a first conductivity;
junction regions of a different second conductivity formed in the active region and separated by a channel; and
an implant of a dopant species in the well, the dopant species comprising a conductivity type such that a conductivity of the implant is the same as the first conductivity of the well and the implant is aligned to the junction regions.

13. The apparatus of claim 12, further comprising a second implant of the dopant species aligned to the junction regions.

14. The apparatus of claim 12, further comprising a gate stack comprising a high-k oxide layer, a metal layer and a polysilicon layer.

15. The system of claim 12, wherein the species is selected from the group consisting of arsenic, phosphorous and antimony.

16. The system of claim 12, wherein the species is boron.
